(19) United States
(12) Patent Application Publication
(10) Pub. No.: US 2013/0000692 A1
(43) Pub. Date: Jan. 3, 2013

(54) METHOD OF MANUFACTURING HELIOSTAT MIRROR WITH SUPPORTING TILE ELEMENTS

(76) Inventor: Jonathan P. Switkes, San Jose, CA (US)

(21) Appl. No.: 13/172,755

(22) Filed: Jun. 29, 2011

(51) Int. Cl. H01L 31/052; B32B 38/10; B32B 37/12; B32B 37/14; G02B 7/182; B32B 37/02

(52) U.S. Cl. 136/246; 359/871; 359/883; 156/60; 156/256

(57) ABSTRACT

A mirror module may include a front plate, a rear plate and a support structure between the front plate and the rear plate. The support structure includes a carrier mesh and multiple tile elements secured to the carrier mesh. The carrier mesh is prefabricated to mount tile elements. During the fabrication of the mirror module, the carrier mesh with tile elements is secured onto the front or rear plate and then secured to the other remaining plate. The mirror module is shaped by assembling the plates and the carrier mesh on a shaping tool or placing the assembled mirror module on a shaping tool. The tile elements may be made of the same material as the front plate or the rear plate to reduce stress on the front plate or rear plate due to temperature fluctuation.

### BACKGROUND OF THE INVENTION

1. Field of the Invention

The present invention relates to mirror modules used in heliostats including tile elements secured to a carrier mesh.

2. Description of the Related Art

Power generation using solar energy has gained much attention as a source of renewable energy. A category of solar power generation system involves focusing solar energy to a central power tower using multitudes of heliostats dispersed in a field. The heliostats reflect and concentrate solar energy onto the central power tower. The central power tower leverages the concentrated light to generate power using either solar thermal energy (STE) or photovoltaics. A commercial power generation system may use hundreds or even thousands of heliostats.

Each heliostat has one or more mirrors for reflecting the solar energy to the central power tower. In order to increase the energy focused on the central power tower, some heliostat mirrors have concaved reflective surfaces. Compared to flat surfaces, the concaved reflective surfaces allow light energy to be concentrated on a smaller area of the central power tower. Further, the heliostat mirrors are controlled by an actuation mechanism to track the trajectory of the sun, and hence, the heliostat mirrors focus the energy onto the central power tower at different times of the day.

The heliostats include mounts for securing heliostat mirrors. Without sufficient rigidity, a heliostat mirror will bend due to its weight when mounted, causing its reflective surface to deform. Moreover, the heliostat mirrors are deployed outdoors where the heliostat mirrors are exposed to various environmental elements such as wind, rain, dust and heat. If the heliostat mirrors do not possess sufficient strength and durability, the environmental elements may cause the heliostat mirrors to deform or crack over time. Such deformed or cracked heliostat mirrors cannot effectively focus the solar energy onto the central power tower, resulting in a lower overall efficiency of the solar power generation system. Eventually, such heliostat mirrors should be replaced or fixed, which adds cost associated with operating the solar power generation system. To reduce the cost, the frequency of replacements and the cost of each heliostat mirror should be minimized to the extent possible.

One of the environmental factors that significantly affect effective operational period of a heliostat mirror is the heat. In many instances, the solar power generation system operates in environment where temperature fluctuates significantly. With changes in the temperature, the heliostat mirror experiences expansion and contraction of its components. Different components in the heliostat mirror may have different coefficients of thermal expansion. As the heliostat mirrors are exposed to repeated temperature fluctuation, the components of heliostat mirrors experience repeated stress and strain. Such repeated stress and strain may eventually cause fatigue destruction of one or more components in the heliostat mirrors.

### SUMMARY OF THE INVENTION

Embodiments of the present invention relate to a mirror module having a support structure between a first plate and a second plate to increase strength and rigidity of the mirror module. The first plate has a reflective surface for reflecting light onto a target. The second plate is separated from the first plate by the support structure. The support structure includes a carrier mesh and a plurality of tile elements secured to the carrier mesh. The support structure is secured between the first plate and the second plate.

In one embodiment, the support structure is prefabricated before assembling the mirror module. The prefabricated support structure is secured between the first plate and the second plate during the assembly of the mirror module. The support structure may be secured to the first plate and the second plate by adhesive.

In one embodiment, the mirror module is shaped into a desired profile by placing the assembled mirror module on a profiled surface before securing structural components to one another. The profiled surface may be curved to form a convex surface or concaved surface on the mirror module.

### BRIEF DESCRIPTION OF THE DRAWINGS

The teachings of the embodiments of the present invention can be readily understood by considering the following detailed description in conjunction with the accompanying drawings.

FIG. 1 is a conceptual diagram illustrating a solar power generation system, according to one embodiment.

FIG. 2A is an exploded view of a mirror module according to one embodiment.

FIG. 2B is a side view of the mirror module of FIG. 2A, according to one embodiment.

FIG. 3 is a rectangular tile element mounted on a carrier mesh, according to one embodiment.

FIGS. 4A through 4C are plan views illustrating various arrangements of tile elements, according to embodiments.

FIG. 5A is a perspective view of a rectangular tile element mounted on a carrier mesh, according to another embodiment.

FIG. 5B is a perspective view of a circular tile element mounted on a carrier mesh, according to one embodiment.

FIG. 5C is a perspective view of a cylindrical tile element mounted on a carrier mesh, according to one embodiment.

FIGS. 6A through 6C are conceptual diagrams illustrating shaping of mirror module on a shaping tool, according to one embodiment.

FIG. 7 is an overall flowchart illustrating a process of manufacturing a mirror module, according to one embodiment.

FIG. 8 is a flowchart illustrating a process of assembling a mirror module, according to one embodiment.

### DETAILED DESCRIPTION OF EMBODIMENTS

The Figures (FIG.) and the following description relate to preferred embodiments of the present invention by way of illustration only. It should be noted that from the following discussion, alternative embodiments of the structures and methods disclosed herein will be readily recognized as viable alternatives that may be employed without departing from the principles of the claimed invention.

Reference will now be made in detail to several embodiments of the present invention(s), examples of which are illustrated in the accompanying figures. It is noted that wherever practicable, similar or like reference numbers may be used in the figures and may indicate similar or like functionality. The figures depict embodiments of the present invention for purposes of illustration only.

Embodiments relate to a mirror module including multiple tile elements mounted on a carrier mesh. The mirror module may include a front plate, a rear plate and a support structure between the front plate and the rear plate. The support structure is prefabricated before assembling with the front plate and the rear plate. During the fabrication of the mirror module, the carrier mesh with tile elements is secured first onto the front or rear plate and then secured to the other remaining plate. The mirror module is shaped by assembling the plates and the carrier mesh on a shaping tool or placing the assembled but unsecured mirror module on a shaping tool. The tile elements may be made of the same material as the front plate or the rear plate to reduce stress on the front plate or the rear plate during temperature fluctuation.

A front plate herein refers to a mirror with a reflective surface formed on a substrate. The reflective surface may be formed by applying a reflective coating (e.g., silver) to the substrate. The substrate may be glass or other transparent materials. The reflective surface is generally formed on an inner surface that is not exposed to the environment.

A rear plate herein refers to a substrate that is spaced away from the front plate. In one embodiment, the rear plate is a substrate made of materials such as glass. The rear plate need not be transparent.

A support structure herein refers to a structure placed between the front plate and the rear plate to increase strength or rigidity of the mirror module. In one embodiment, the support structure includes a carrier mesh and tile elements mounted on the carrier mesh. The tile elements may be made of the same material as the front plate or the rear plate.

### Overall Architecture of Solar Power Generator System

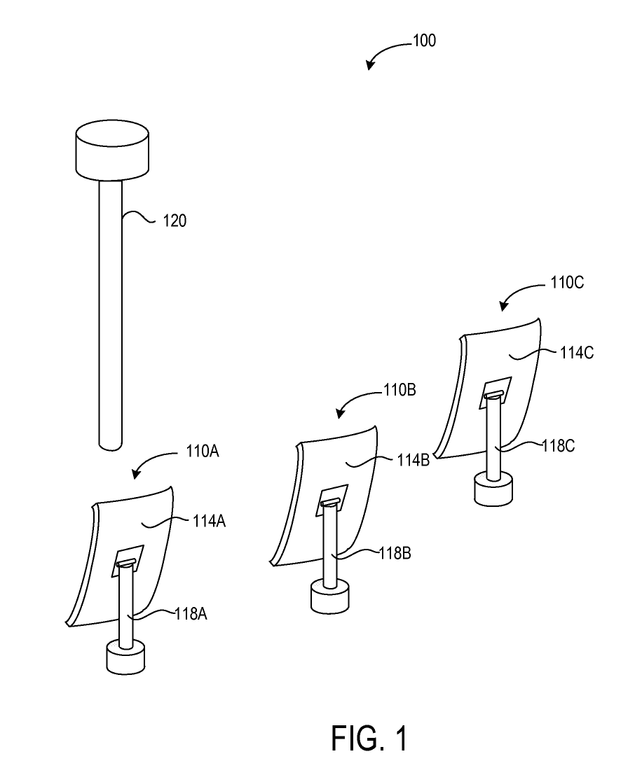

FIG. 1 is a conceptual diagram illustrating a solar power generation system 100, according to one embodiment. The solar power generating system 100 may include, among other components, a central power tower 120 and multiple heliostats 110A through 110C (hereinafter collectively referred to as “the heliostats 110”). Although only three heliostats 100 are illustrated in FIG. 1, there may be hundreds or even thousands of heliostats deployed in the solar power generation system 100.

The heliostats 110 reflect and focus solar energy onto the central power tower 120. For this purpose, each heliostat 110 includes a mirror module 114A, 114B or 114C (hereinafter collectively referred to as the “mirror modules 114” or individually as “mirror module 114”). The front surface of the mirror modules 114 may be flat or concaved. The heliostats 110 also include mounts 118A through 118C (hereinafter collectively referred to as the “mounts 118”) onto which the mirror modules 114 are mounted. The heliostats 110 may also include actuating devices (not shown) to move the heliostats 110 relative to the mounts 118.

The central power tower 120 receives the solar energy from the heliostat mirrors 110 and generates electricity using a solar thermal system, photovoltaic solar cells or a combination thereof. The solar power system 100 may include a centralized or distributed control system (not shown) for adjusting the tilting and orientation of the heliostat mirrors 110 to increase the amount of solar energy sent to the central power tower 120.

### Example Structure of Mirror Module

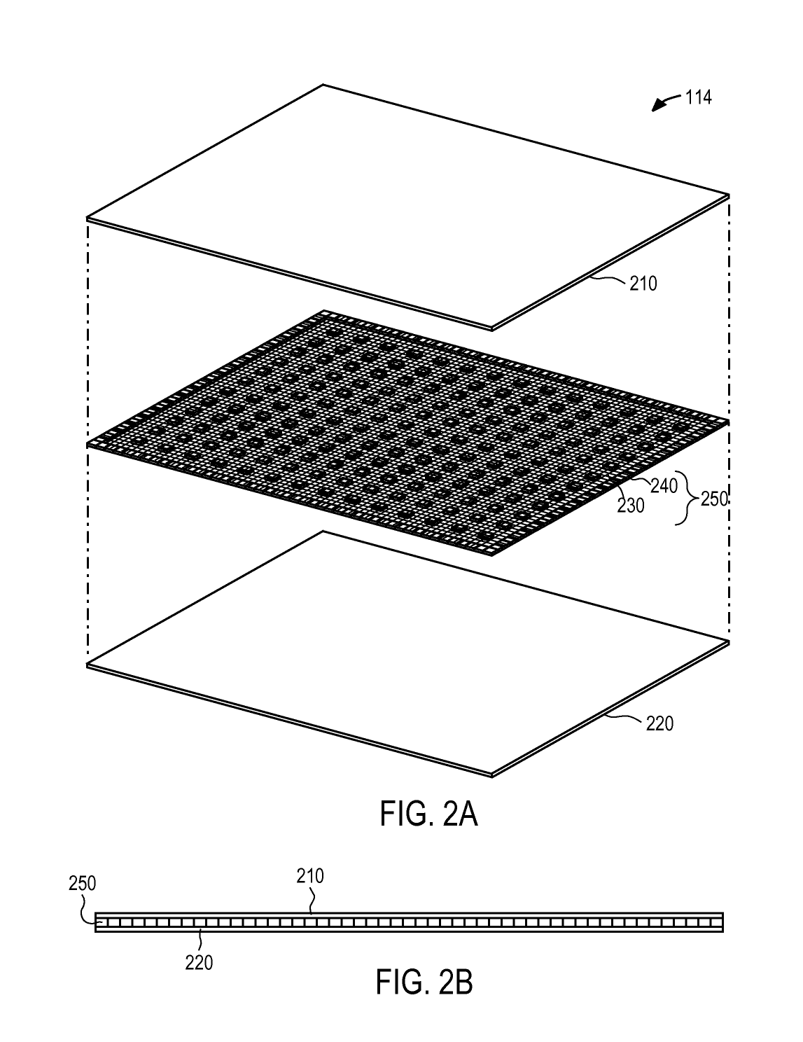

FIG. 2 is an exploded view of a mirror module 114 according to one embodiment. The mirror module 114 may include, among other components, a front plate 210, a rear plate 220, and a support structure 250. The front plate 210 includes a reflective surface for reflecting the light to the central power tower 120. In one embodiment, the reflective surface is formed on the rear surface of the front plate 210 facing the support structure 250. The rear plate 220 may include fixing structures (not shown) for securing to a mount 118 and connecting structures for connecting to an actuation mechanism control. The fixing structures and connecting structures, for example, include brackets, holes for receiving screws, and frames. In one embodiment, the rear plate 220 may be fabricated to include such fixing structures. Alternatively, such fixing structures may be added to the rear plate 220 after the fabrication of the rear plate 220.

The support structure 250 provides strength and rigidity to the mirror module 114. The support structure 250 may include, among other components, a carrier mesh 230 and tile elements 240. The tile elements 240 are secured to the carrier mesh 230 by means of, for example, adhesive in a separate fabrication process before assembly with the front plate 210 and the rear plate 220. Using the support structure 250 with tile elements 240 secured onto the carrier mesh 230 has, among other advantages, simplifying the process of manufacturing the mirror module 114. That is, during the manufacturing of the mirror module 114, individual pieces of the tile elements need not be picked, placed and secured at predetermined locations of the front plate 210 or the rear plate 220. Rather, the support structure 250 may be pulled, cut and secured between the front plate 210 and the rear plate 220 in a convenient manner. Further, the carrier 230 may increase the tensile strength of the support structure 250 and also prevent shattered or cracked pieces of the tile elements 240 from being scattered around during or after manufacturing of the mirror module 114.

Any flexible fabric or textile can be used as the carrier mesh 230. The thread or yarn of the carrier mesh 230 may be loosely weaved or knit to reduce the cost of the carrier mesh 230. Since adhesive for securing the tile elements 240 to the carrier mesh 230 binds the thread or yarn, the carrier mesh 230 can be coarsely weaved or knitted. In one embodiment, the carrier mesh 230 is made of polyester.

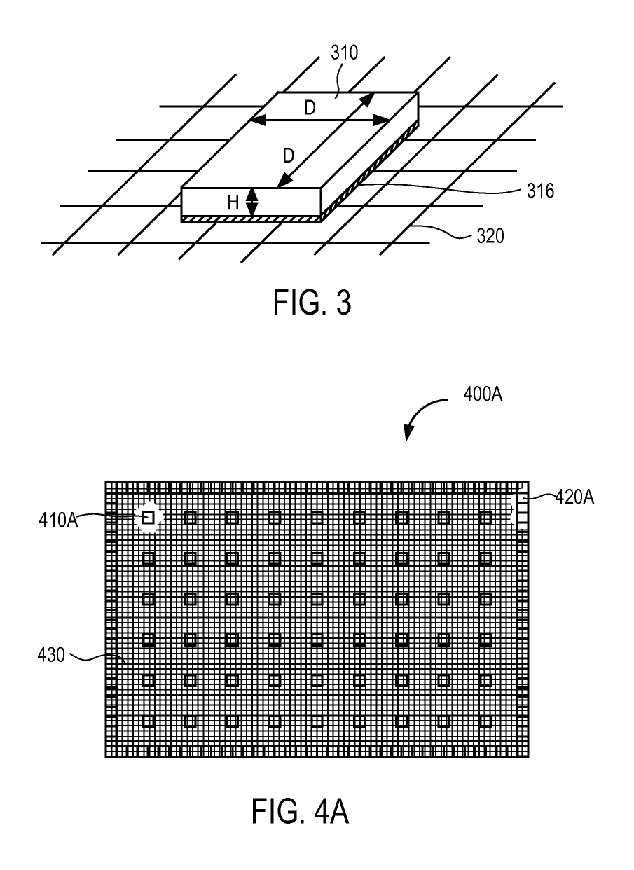

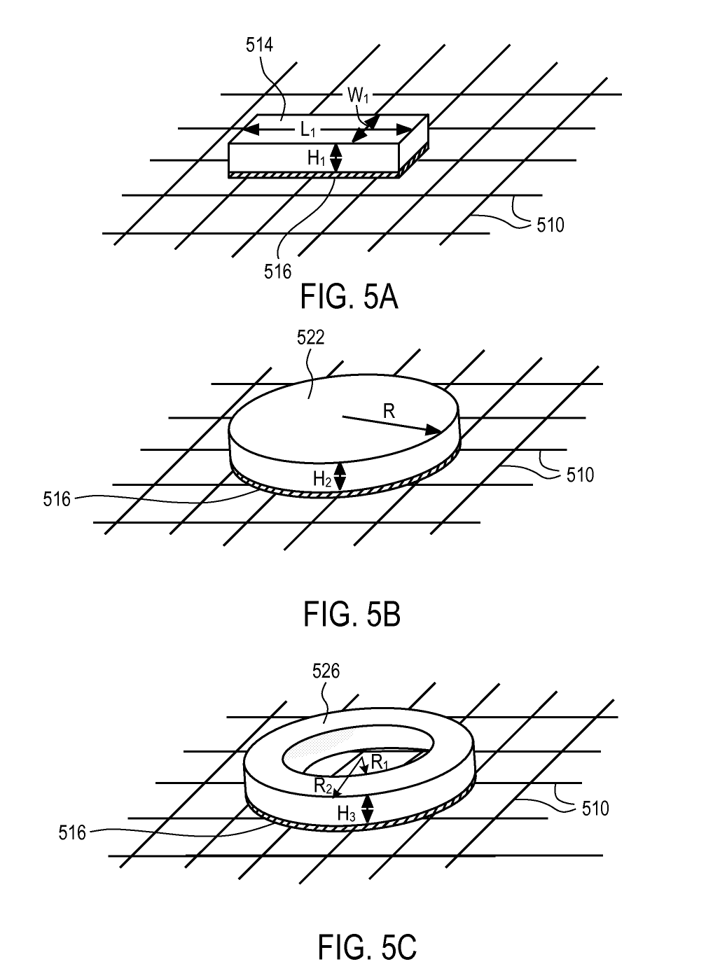

The tile element 240 may be made of any materials. However, if components in the mirror module 114 have different coefficients of thermal expansion, the components of the mirror module can experience increased stress due to different degrees of thermal expansion. Hence, it is preferable to use the same material as the front plate 210 or the rear plate 220. The tile elements 240 can be shaped as a square or various other shapes, as described below in detail with reference to FIGS. 3 and 5A through 5D.

In one embodiment, the thickness of the front plate 210 and the thickness of the rear plate 210 are 3 mm, respectively.

### Example Support Structures

FIG. 3 is a perspective view of a tile element 310 according to one embodiment. The tile element 310 is square shaped with the length of D, the width of D and the height of H. In one embodiment, the height H is 8 mm. The tile element 310 is secured to a carrier mesh 320 by a layer of adhesive 316. Epoxy or any other adhesive may be used for this purpose. Alternatively, the tile elements 310 or the carrier mesh 320 may be melted and solidified to secure the tile elements 310 to the carrier mesh 320 instead of using adhesive 316.

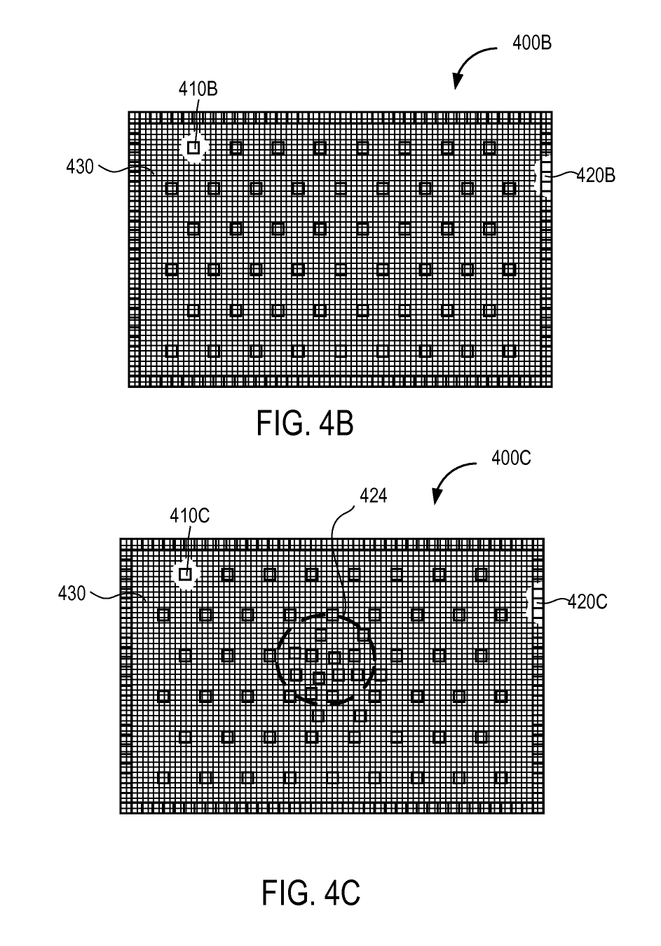

FIG. 4A is a plan view of a support structure 400A, according to one embodiment. The support structure 400 includes a carrier mesh 430 and tile elements 410A, 420A. The edges of the carrier mesh 430 are surrounded by abutting tile elements 420A. After being secured between the front plate 210 and the rear plate 220, the abutting tile elements 420A shield the interior of the mirror module 114 from dusts and other external pollutants. The tile elements 410A other than the tile elements 420A at the edges are spaced away from each other in columns and rows. The number of the tile elements 410 and the distance between the tile elements 410 may be varied depending on the weight, dimension or other configurations of the mirror module 114.

FIG. 4B is a plan view of a support structure 400B, according to one embodiment. The support structure 400B is different from the support structure 400A of FIG. 4A in that the tile elements 410B are placed in rows and columns in a staggered manner. As in the example of FIG. 4A, the tile elements 420B at the edges of the support structure 400B abut each other to shield the interior of the mirror module 114 from dusts and other external pollutants.

FIG. 4C is a plan view of support structure 400C, according to one embodiment. The support structure 400C has an uneven distribution of tile elements 420C. Specifically, the tile elements 420C are more densely placed in a region 424 where the mirror module 114 is secured to a mount 118. The region 424 of the support structure 400C receives and sustains greater force compared to other regions of the support structure 400C. Hence, the region 424 has more tile elements 420C compared to other regions of the support structure 400C. As in the embodiments of FIGS. 4A and 4B, the tile elements 420C at the edges of the support structure 400C abut each other to shield the interior of the mirror modules 114 from dusts and other external pollutants.

In one embodiment, abutting tile elements 420A through 420C are replaced with separate shielding elements. For example, long rib structures extending across the edges may be used instead of the tile elements 420A through 420C. The long rib structures are separate from the support structure 400A through 400C, and may be placed on the front plate 210 or the rear plate 220 during the assembly of the mirror module.

FIG. 5A is a perspective view of a rectangular tile element 516 on a carrier mesh 510, according to one embodiment. The tile element 516 has the length of L₁, width W₁ and the height of H₁. The tile element 516 is secured to the carrier mesh 510 by a layer 516 of adhesive.

FIG. 5B is a perspective view of a circular tile element 522 on the carrier mesh 510, according to one embodiment. The circular tile element 522 has the outer radius of R and the height of H₂. The circular tile element 522 is secured to the carrier mesh 510 via a layer 516 of adhesive.

FIG. 5C is a perspective view of a cylindrical tile element 526 on the carrier mesh 510, according to one embodiment. The cylindrical tile element 526 has the inner radius of R₁, the outer radius of R₂ and the height of H₃. By forming a hole in the center of the cylindrical tile element 526, the weight of the tile element 526 and the material used in the tile element 526 can be reduced. The cylindrical tile element 526 is secured to the carrier mesh 510 by a layer 516 of adhesive.

The tile elements illustrated in FIGS. 3 and 5A through 5C are merely illustrative, and tiles structures of other configuration may be also be placed on a carrier mesh 510 to form the supporting structure. Further, a combination of various tile elements may be used. For example, the cylindrical tile elements 526 are dispersed within the edges of a support structure whereas the rectangular tile elements 514 are placed at the edges of the support structure.

In one embodiment, the support structure is prefabricated before the support structure is assembled with the front plate 210 and the rear plate 220 into the mirror module 114. The support structure is fabricated, for example, by applying adhesive to the tile elements or the carrier mesh and then placing the tile elements on the carrier mesh. Then the adhesive is cured to secure the tile elements to the carrier mesh. After the tile elements are secured onto the carrier mesh, the support structure may be rolled for storage or transport.

### Example Method of Manufacturing Mirror Module

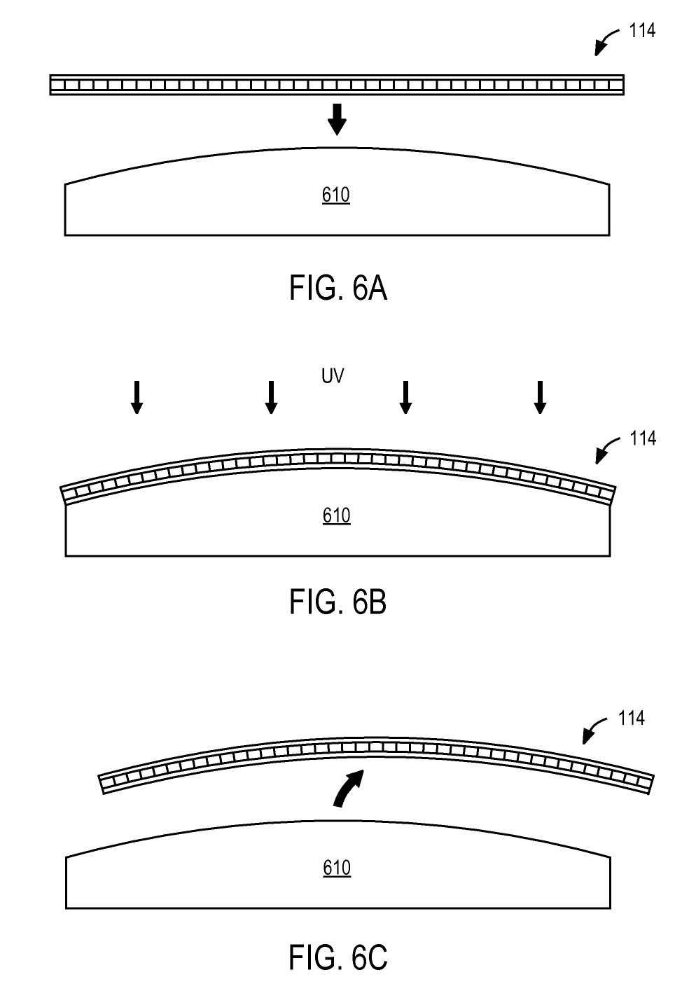

FIGS. 6A through 6C are conceptual diagrams illustrating shaping of the mirror module 114 on a shaping tool 610, according to one embodiment. The shaping tool 610 has a curved upper surface. Initially, the assembled mirror module 114 has a flat shape or other random shape, as illustrated in FIG. 6A. In one embodiment, the mirror module 114 is assembled by applying adhesive between the front plate and the support structure as well as between the rear plate and the support structure. Before the adhesive is cured, the mirror module 114 is placed on the shaping tool 610 and at least partially cured (e.g., by exposing the mirror module 114 to ultraviolet light or heating the mirror module 114), as illustrated in FIG. 6B. After the adhesive is partially or fully cured, the mirror module 114 is removed from the shaping tool 610, as illustrated in FIG. 6C.

In one embodiment, to ensure that the mirror module 114 is shaped as desired, suction holes (connected to a vacuum pump) are formed on the shaping tool 610 to pull the mirror module 114 towards the shaping tool. The suction holes are placed at negative pressure to attract the mirror module 114 toward the shaping 610. Alternatively or in addition to pulling the mirror module 114 by the suction holes, a press or weight may exert pressure onto the mirror module 114 to push the mirror module towards the shaping tool 610.

Although the shaping tool 610 is illustrated as having a convex shape, the shaping tool 610 may be flat, concaved or have other shapes depending on the desired shape of the mirror module 114.

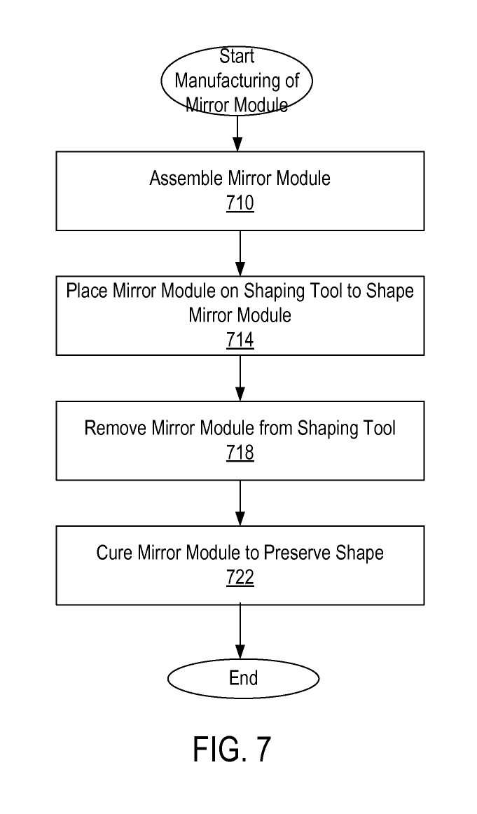

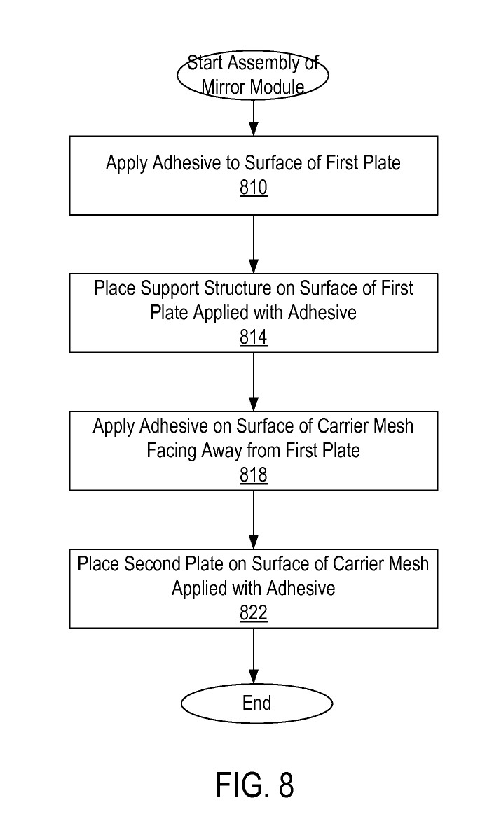

FIG. 7 is a flowchart for manufacturing the mirror module 114, according to one embodiment. First, the mirror module 114 is assembled 710, as described below in detail with reference to FIG. 8. The mirror module 114 can be assembled, for example, on an assembly table. The assembled mirror module 114 is placed 714 on the shaping tool 610 to shape the mirror module 714 into a desired configuration. For example, the mirror module 714 is shaped to have a concaved shaped. After the mirror module 114 is shaped by partially or totally curing the adhesive, the mirror module 114 is removed 718 from the shaping tool 610, for example, by exposing to ultraviolet light. Further, the mirror module 114 may be fully cured 722, for example, by baking the mirror module 114 in an oven. If the mirror module 114 is fully cured on the shaping tool 610, a separate baking step may be omitted.

In an alternative embodiment, the mirror module 710 may be assembled on the shaping tool 610, and shaped on the shaping tool 610. The mirror module 716 while mounted on the shaping tool 610 may be carried onto an oven or other device for curing the adhesive.

FIG. 8 is a flowchart illustrating the process of assembling the mirror module 114, according to one embodiment. A first plate (e.g., front plate 210) is placed on an assembling surface. The assembling surface may be the surface of the shaping tool 610 or a different tool. Adhesive is applied 810 to the surface of the first plate facing away from the assembling surface. A screen printing method, for example, is used to apply the adhesive on desired locations of the first plate. A compressed air adhesive dispenser may also be used to apply adhesive. Preferably, the adhesive is coated at locations where the tile elements are to be located.

The support structure 250 is then placed 814 on the first plate to secure the support structure. Prefabricated support structures may be stored in the form of a roll. The support structure 250 may be unrolled, placed on the first plate and then be cut along the edge of the first plat. Alternative, the prefabricated support structure may be provided in the form of individual sheets that are picked up and placed on the first plate. As described above in detail with reference to FIG. 2A, the support structure may include a carrier mesh and tile elements mounted on the carrier mesh. By having the tile elements mounted on the carrier mesh, the process of manufacturing the support structure 250 can be simplified since an entire sheet of tile elements can be placed in a single step instead of applying adhesive and securing tile elements to the first plate individually.

The surface of the support structure 250 facing away from the first plate is then applied 818 with adhesive. The screen printing method, for example, is used to apply the adhesive on desired locations of the support structure 250. Preferably, the adhesive is applied to the tile elements of the support structure 250. The second plate (e.g., rear plate 220) is then placed 822 on the support structure 250 to obtain the mirror module 114.

Instead of using adhesive to fabricate the support structure or the mirror module, the tile elements may be melted to secure the tile elements to the carrier mesh or to secure the support structure to the front plate 210 or the rear plate 220. If the tile elements are made of plastic, for example, the tile elements can be melted at relatively low temperature. Alternatively, the carrier mesh may be melted to secure the tile elements. Also, instead of using adhesive, a solvent may be used to first dissolve the surface of the tile elements or the carrier mesh and then secure the tile elements to the carrier mesh, the front plate 210 or the rear plate 220.

Although support structures are described above primarily with respect to mirror modules used in heliostats, the same support structure may also be used in mirrors for other purposes such as decorative wall mirrors, parabolic troughs for collecting solar energy and mirrors in solar dishes.

Upon reading this disclosure, those of ordinary skill in the art will appreciate still additional alternative structural and functional designs through the disclosed principles of the present invention. Thus, while particular embodiments and applications of the present invention have been illustrated and described, it is to be understood that the invention is not limited to the precise construction and components disclosed herein and that various modifications, changes and variations which will be apparent to those skilled in the art may be made in the arrangement, operation and details of the method and apparatus of the present invention disclosed herein without departing from the spirit and scope of the invention as defined in the appended claims.

What is claimed is:

1. A mirror module, comprising:
a first plate having a reflective surface for reflecting light onto a target;
a second plate separated from the first plate; and
a support structure secured between an inner surface of the first plate and an inner surface of the second plate, the support structure comprising a carrier mesh and a plurality of tile elements secured to the carrier mesh.

2. The mirror module of claim 1, wherein the first plate, the second plate and the tile elements are made of a same material

3. The mirror module of claim 1, wherein the support structure comprises a plurality of abutting tile elements surrounding edges of the mirror module.

4. The mirror module of claim 1, wherein the mirror module comprises a first layer of adhesive between the first plate and the support structure, and a second layer of adhesive between the second plate and the support structure.

5. The mirror module of claim 4, wherein the first layer of adhesive and the second layer of adhesive are applied by screen printing.

6. The mirror module of claim 1, wherein the support structure comprises a layer of adhesive securing the tile elements to the carrier mesh.

7. The mirror module of claim 1, wherein a density of the tile elements in a region where the mirror module is connected to a mount is higher than densities of the tile elements in other regions of the mirror module.

8. The mirror module of claim 1, wherein each tile element is shaped as one of a square, a rectangle, a circular or a cylinder.

9. The mirror module of claim 1, wherein the reflective surface is concaved.

10. A method of manufacturing a mirror module, comprising:
assembling the mirror module by securing a support structure between a first plate and a second plate, the support structure comprising a carrier mesh and a plurality of tile elements attached to the carrier mesh;
placing the assembled mirror module on a profiled surface; and
shaping the assembled mirror module on the profiled surface.

11. The method of claim 10, wherein assembling the mirror module comprises:
placing the first plate on an assembling surface,
applying first adhesive on a surface of the first plate facing away from the assembling surface or surfaces of the plurality of tile elements facing the first plate;
placing the plurality of tile elements on the first plate;
applying second adhesive on surfaces of the plurality of tile elements facing away from the first plate or on a surface of the second plate facing the plurality of tile elements; and
placing the second plate on the tile elements.

12. The method of claim 11, wherein shaping the assembled mirror module comprises at least partially curing the first adhesive and the second adhesive.

13. The method of claim 12, wherein at least partially curing the first adhesive and the second adhesive comprise exposing the mirror module to ultraviolet light.

14. The method of claim 11, wherein assembling the mirror module further comprises:
unrolling the support structure onto the first plate; and
cutting the unrolled support structure according to a dimension of the first plate.

15. The method of claim 10, further comprising pressing the mirror module onto the profile surface.

16. The method of claim 10, further comprising wherein the profiled surface is a concaved surface or convex surface.

17. The method of claim 10, wherein the first plate, the second plate and the plurality of tile elements are made of a same material.

18. The method of claim 10, wherein each tile element is shaped as one of a square, a rectangle, a circular or a cylinder.

19. The method of claim 10, further comprising heating the shaped the assembled mirror.

20. A solar power generation system comprising:
a plurality of heliostats, each heliostat comprising:
a first plate having a reflective surface for reflecting light onto a power tower,
a second plate separated from the first plate, and
a support structure secured between an inner surface of the first plate and an inner surface of the second plate, the support structure comprising a carrier mesh and a plurality of tile elements secured to the carrier mesh; and
the power tower configured to generate electricity based on solar energy reflected by the plurality of heliostats.
